(19) United States
(12) Patent Application Publication
(10) Pub. No.: US 2026/0059820 A1
(43) Pub. Date: Feb. 26, 2026

(54) SEMICONDUCTOR STRUCTURE AND MANUFACTURING METHOD THEREFOR

(71) Applicant: ENKRIS SEMICONDUCTOR, INC., Suzhou (CN)

(72) Inventors: Jiaqi HE, Suzhou (CN); Kai CHENG, Suzhou (CN)

(73) Assignee: ENKRIS SEMICONDUCTOR, INC., Suzhou (CN)

(21) Appl. No.: 18/903,387

(22) Filed: Oct. 1, 2024

(30) Foreign Application Priority Data
Aug. 21, 2024 (CN) 202411154999.5

(51) Int. Cl. H01L 29/20; H01L 29/06; H01L 29/66; H01L 29/778

(52) U.S. Cl. CPC H10D 62/8503; H10D 30/015; H10D 30/477; H10D 62/124

(57) ABSTRACT

A semiconductor structure includes a substrate, an N+ type gallium nitride epitaxial layer, an N− type gallium nitride epitaxial layer and a first AlGaN layer which are sequentially disposed; a P-type gallium nitride epitaxial layer extending from a surface of a side, away from the substrate, of the first AlGaN layer into the N− type gallium nitride epitaxial layer; and a second AlGaN layer located on a side, away from the substrate, of the first AlGaN layer and the P-type gallium nitride epitaxial layer. According to technical solutions of the present disclosure, an enhancement mode device with a high threshold voltage can be realized and an on-resistance of the device can be reduced.

### CROSS-REFERENCE TO RELATED APPLICATIONS

The present application claims priority to Chinese Patent Application No. 202411154999.5, filed on Aug. 21, 2024, which is hereby incorporated by reference in its entirety.

### TECHNICAL FIELD

The present disclosure relates to the field of semiconductor technologies, and in particular, to a semiconductor structure and a manufacturing method for the semiconductor structure.

### BACKGROUND

A Gallium nitride (GaN) material, as a typical representation of the third generation of wide band gap semiconductor materials, has a band gap width of 3.4 eV, and has characteristics, such as a higher critical breakdown electric field, a higher electron saturation drift velocity, a higher limit working temperature, a smaller dielectric constant and greater chemical stability than traditional silicon materials, which is an excellent material for manufacturing power electronic power semiconductor devices and has broad market prospects.

Since a current GaN bulk material technology is not mature enough, GaN devices are usually epitaxial-based lateral structure devices. A main disadvantage of a lateral structure device is that a breakdown voltage of a device is proportional to a spacing between electrodes, which results in that a larger device size is required in a high-voltage working scenario, thereby increasing the overall complexity and process preparation cost of high-voltage and high-power devices.

A distance of a vertical structure device in a vertical direction may be increased by increasing a thickness of an epitaxial layer without increasing a device size, thereby improving a withstand voltage level of the device, and further realizing high-speed and high-current output. However, a traditional vertical device only conducts current through a bulk material in a longitudinal direction, so that an electron mobility is not high and a conduction range is limited, and an on-resistance is large. Meanwhile, since GaN is an intrinsic N-type material and has conductivity, a gate structure prepared on a top surface of the traditional vertical device has a poor gate control capability, and it is difficult to realize an enhancement mode device with a high threshold voltage.

### SUMMARY

In view of this, embodiments of the present disclosure provide a semiconductor structure and a manufacturing method for the semiconductor structure, to further improve a mobility of a vertical structure device and realize an enhancement mode device with a high threshold voltage.

According to an aspect of the present disclosure, an embodiment of the present disclosure provides a semiconductor structure, which includes: a substrate, an N+ type gallium nitride epitaxial layer, an N− type gallium nitride epitaxial layer and a first AlGaN layer that are sequentially disposed; a P-type gallium nitride epitaxial layer extending from a surface of a side, away from the substrate, of the first AlGaN layer into the N− type gallium nitride epitaxial layer; and a second AlGaN layer located on a side, away from the substrate, of the first AlGaN layer and the P-type gallium nitride epitaxial layer.

As an optional embodiment, a thickness of the second AlGaN layer ranges from 10 nm to 100 nm.

As an optional embodiment, the second AlGaN layer includes an N-type doped ion.

As an optional embodiment, the semiconductor structure further includes: a source electrode extending from a surface of a side, away from the substrate, of the second AlGaN layer into the P-type gallium nitride epitaxial layer; a dielectric layer located on a side, away from the substrate, of the second AlGaN layer and the source electrode; a drain electrode located on a side, away from the dielectric layer, of the substrate; and a gate electrode located on a side, away from the substrate, of the dielectric layer and corresponding to the P-type gallium nitride epitaxial layer.

As an optional embodiment, a material of the dielectric layer includes at least one of silicon nitride, aluminum oxide, aluminum nitride and aluminum oxynitride.

As an optional embodiment, a projection of the gate electrode on a plane where the substrate is located completely covers a projection of a surface of a side, close to the second AlGaN layer, of the P-type gallium nitride epitaxial layer on the plane where the substrate is located.

As an optional embodiment, a projection area of the source electrode on a plane where the substrate is located is smaller than a projection area of the P-type gallium nitride epitaxial layer on the plane where the substrate is located.

As an optional embodiment, a projection of the source electrode on the plane where the substrate is located is completely located in a projection of the P-type gallium nitride epitaxial layer on the plane where the substrate is located.

As an optional embodiment, a material of the source electrode includes an N-type heavily doped material.

As an optional embodiment, a thickness of the P-type gallium nitride epitaxial layer located below the source electrode is greater than 50 nm, and a width of the P-type gallium nitride epitaxial layer located on a side of a sidewall of the source electrode is greater than 500 nm.

As an optional embodiment, a two-dimensional electron gas is formed on an interface of the first AlGaN layer and the N− type gallium nitride epitaxial layer.

According to another aspect of the present disclosure, an embodiment of the present disclosure provides a manufacturing method for a semiconductor structure, which includes: sequentially disposing a substrate, an N+ type gallium nitride epitaxial layer, an N− type gallium nitride epitaxial layer and a first AlGaN layer; etching the first AlGaN layer and the N− type gallium nitride epitaxial layer to form a trench with a bottom located in the N− type gallium nitride epitaxial layer; performing a secondary epitaxy of a P-type gallium nitride epitaxial layer in the trench; and growing a second AlGaN layer on the P-type gallium nitride epitaxial layer and the first AlGaN layer.

As an optional embodiment, a thickness of the P-type gallium nitride epitaxial layer located below the source electrode is greater than 50 nm, and a width of the P-type gallium nitride epitaxial layer located on a side of a sidewall of the source electrode is greater than 500 nm.

As an optional embodiment, the manufacturing method for the semiconductor structure further includes: performing ion implantation on a surface of a side, away from the substrate, of the second AlGaN layer to form a source electrode extending into the P-type gallium nitride epitaxial layer; and disposing a dielectric layer on a side, away from the substrate, of the second AlGaN layer and the source electrode, disposing a drain electrode on a side, away from the dielectric layer, of the substrate, and disposing a gate electrode corresponding to the P-type gallium nitride epitaxial layer, on a side, away from the substrate, of the dielectric layer.

As an optional embodiment, the performing a secondary epitaxy of a P-type gallium nitride epitaxial layer in the trench includes: performing a secondary epitaxy of an initial P-type gallium nitride epitaxial layer in the trench, where a thickness of the initial P-type gallium nitride epitaxial layer is greater than a depth of the trench; and chemically and mechanically polishing the initial P-type gallium nitride epitaxial layer to obtain the P-type gallium nitride epitaxial layer, where a thickness of the P-type gallium nitride epitaxial layer is equal to the depth of the trench.

As an optional embodiment, a method of performing the secondary epitaxy of the P-type gallium nitride epitaxial layer in the trench is in-situ growth.

As an optional embodiment, an ion implanted on the surface of the side, away from the substrate, of the second AlGaN layer includes a silicon ion.

As an optional embodiment, a thickness of the second AlGaN layer ranges from 10 nm to 100 nm.

As an optional embodiment, the second AlGaN layer includes an N-type doped ion.

As an optional embodiment, an interface of the first AlGaN layer and the N− type gallium nitride epitaxial layer is configured to generate a two-dimensional electron gas.

### BRIEF DESCRIPTION OF THE DRAWINGS

FIG. 1 is a schematic structural diagram of a semiconductor structure according to an embodiment of the present disclosure.

FIG. 2 is a flowchart of a manufacturing method for a semiconductor structure according to an embodiment of the present disclosure.

FIG. 3 to FIG. 8 are schematic structural diagrams of intermediate structures in a process of manufacturing a semiconductor structure according to an embodiment of the present disclosure.

### DETAILED DESCRIPTION OF THE EMBODIMENTS

Technical solutions in embodiments of the present disclosure are described clearly and completely below with reference to the accompanying drawings of the embodiments of the present disclosure. Apparently, the described embodiments are only a part, but not all of the embodiments of the present disclosure. All other embodiments that may be obtained by those of ordinary skill in the art based on the embodiments in the present disclosure without any inventive efforts fall into the protection scope of the present disclosure.

In order to further improve a mobility of a vertical structure device and realize an enhancement mode device with a high threshold voltage, a semiconductor structure and a manufacturing method therefor are provided in the present disclosure. The semiconductor structure includes: a substrate, an N+ type gallium nitride epitaxial layer, an N− type gallium nitride epitaxial layer, and a first AlGaN layer that are sequentially disposed, a P-type gallium nitride epitaxial layer extending from a surface of a side, away from the substrate, of the first AlGaN layer into the N- type gallium nitride epitaxial layer; and a second AlGaN layer located on a side, away from the substrate, of the first AlGaN layer and the P-type gallium nitride epitaxial layer. According to the present disclosure, on one hand, a depletion region formed by the second AlGaN layer and the P-type gallium nitride epitaxial layer may be controlled through a gate electrode, thereby controlling a switch of a device without a need for a large gate electrode current to control the P-type gallium nitride epitaxial layer, and realizing an enhancement mode device with a high threshold voltage; on the other hand, a two-dimensional electron gas is generated by setting the N− type gallium nitride epitaxial layer and the first AlGaN layer, to expand a current transmission range, thereby reducing an on-resistance of a device.

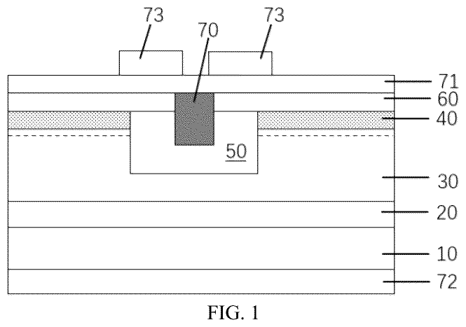

A semiconductor structure and a manufacturing method therefor mentioned in the present disclosure are further illustrated with examples below with reference to FIG. 1 to FIG. 8.

FIG. 1 is a schematic structural diagram of a semiconductor structure according to an embodiment of the present disclosure. As shown in FIG. 1, the semiconductor structure includes: a substrate 10, an N+ type gallium nitride epitaxial layer 20, an N− type gallium nitride epitaxial layer 30 and a first AlGaN layer 40 that are sequentially disposed; a P-type gallium nitride epitaxial layer 50 extending from a surface of a side, away from the substrate 10, of the first AlGaN layer 40 into the N− type gallium nitride epitaxial layer 30; and a second AlGaN layer 60 located on a side, away from the substrate 10, of the first AlGaN layer 40 and the P-type gallium nitride epitaxial layer 50. Furthermore, the semiconductor structure further includes: a source electrode 70 extending from a surface of a side, away from the substrate 10, of the second AlGaN layer 60 into the P-type gallium nitride epitaxial layer 50. The first AlGaN layer 40 and the N− type gallium nitride epitaxial layer 30 may form a heterojunction, so that a two-dimensional electron gas is formed on an interface of the first AlGaN layer 40 and the N− type gallium nitride epitaxial layer 30. Optionally, the second AlGaN layer 60 includes an N-type doped ion, which may further improve a concentration of the two-dimensional electron gas. As shown in FIG. 1, the semiconductor structure further includes: a dielectric layer 71 located on a side, away from the substrate, of the second AlGaN layer 60 and the source electrode 70; a drain electrode 72 located on a side, away from the dielectric layer 71, of the substrate 10; and a gate electrode 73 located on a side, away from the substrate 10, of the dielectric layer 71 and corresponding to the P-type gallium nitride epitaxial layer 50. A working principle of the semiconductor structure provided in the present disclosure is: when the gate electrode 73 is floating, a space charge (depletion) layer is formed between the P-type gallium nitride epitaxial layer 50 and the second AlGaN layer 60, that is, a reverse biased PN junction, and a device is turned off; and when the gate electrode 73 is added a positive voltage greater than a threshold voltage, a conductive channel is formed on an interface between the dielectric layer 71 and the second AlGaN layer 60, so that the device is turned on, thereby realizing an enhancement mode device.

In this embodiment, a material of the substrate 10 includes Si, SiC, GaN, sapphire or diamond. Materials of the N+ type gallium nitride epitaxial layer 20, the N− type gallium nitride epitaxial layer 30 and the P-type gallium nitride epitaxial layer 50 include gallium nitride-based materials, such as GaN, AlGaN, or InGaN. A material of the source electrode 70 includes an N-type heavily doped material. A material of the dielectric layer 71 includes at least one of silicon nitride, aluminum oxide, aluminum nitride and aluminum oxynitride.

In this embodiment, a projection area of the source electrode 70 on a plane where the substrate 10 is located is smaller than a projection area of the P-type gallium nitride epitaxial layer 50 on the plane where the substrate 10 is located. Optionally, a projection of the source electrode 70 on the plane where the substrate 10 is located is completely located in a projection of the P-type gallium nitride epitaxial layer 50 on the plane where the substrate 10 is located. The source electrode 70 is completely located in the P-type gallium nitride epitaxial layer 50, a thickness of the P-type gallium nitride epitaxial layer 50 located below the source electrode 70 is greater than 50 nm, and a width of the P-type gallium nitride epitaxial layer 50 located on a side of a sidewall of the source electrode 70 is greater than 500 nm, so that a normally-off state of the device may be achieved, and direct conduction between the source electrode 70 and the drain electrode 72 is avoided. A projection of the gate electrode 73 on the plane where the substrate 10 is located completely covers a projection of a surface of a side, close to the second AlGaN layer 60, of the P-type gallium nitride epitaxial layer 50 on the plane where the substrate 10 is located. The gate electrode 73 may implement the switch of the device by controlling a depletion region formed by the second AlGaN layer 60 and the P-type gallium nitride epitaxial layer 50. A thickness of the second AlGaN layer 60 may affect the control capability of the gate electrode 73 on the depletion region, and the thickness of the second AlGaN layer 60 ranges from 10 nm to 100 nm. When the thickness of the second AlGaN layer 60 is too small, the second AlGaN layer 60 is completely depleted by the P-type gallium nitride epitaxial layer 50 and a large gate voltage is required to turn on the device. When the thickness of the second AlGaN layer 60 is too large, the P-type gallium nitride epitaxial layer 50 is difficult to completely deplete the second AlGaN layer 60, and the device remains in a normally-off state and cannot implement an enhancement mode device.

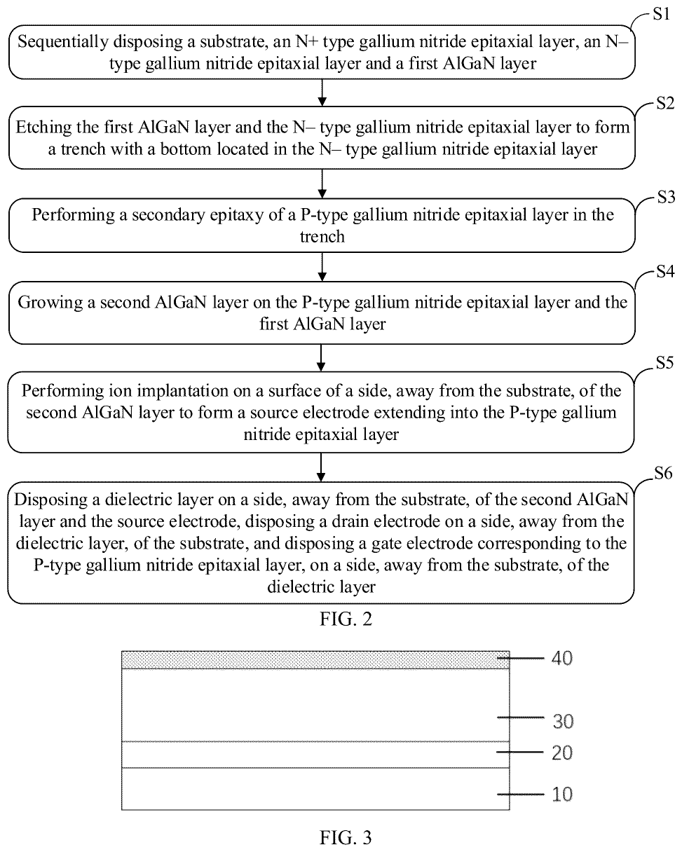

According to another aspect of the present disclosure, an embodiment of the present disclosure provides a manufacturing method for a semiconductor structure. FIG. 2 is a flowchart of a manufacturing method for a semiconductor structure according to an embodiment of the present disclosure, and FIG. 3 to FIG. 8 are schematic structural diagrams of intermediate structures in a process of manufacturing a semiconductor structure according to an embodiment of the present disclosure. As shown in FIG. 2, the manufacturing method for the semiconductor structure provided by an embodiment of the present disclosure may include the following steps.

S1: sequentially disposing a substrate, an N+ type gallium nitride epitaxial layer, an N- type gallium nitride epitaxial layer and a first AlGaN layer.

Specifically, as shown in FIG. 3, the substrate 10, the N+ type gallium nitride epitaxial layer 20, the N− type gallium nitride epitaxial layer 30 and the first AlGaN layer 40 are sequentially disposed. A material of the substrate 10 includes Si, SiC, GaN, sapphire or diamond. Materials of the N+ type gallium nitride epitaxial layer 20 and the N− type gallium nitride epitaxial layer 30 include gallium nitride-based materials, such as GaN, AlGaN or InGaN. The first AlGaN layer 40 and the N− type gallium nitride epitaxial layer 30 may form a heterojunction, so that an interface of the first AlGaN layer 40 and the N− type gallium nitride epitaxial layer 30 may generate a two-dimensional electron gas.

S2: etching the first AlGaN layer and the N− type gallium nitride epitaxial layer to form a trench with a bottom located in the N− type gallium nitride epitaxial layer.

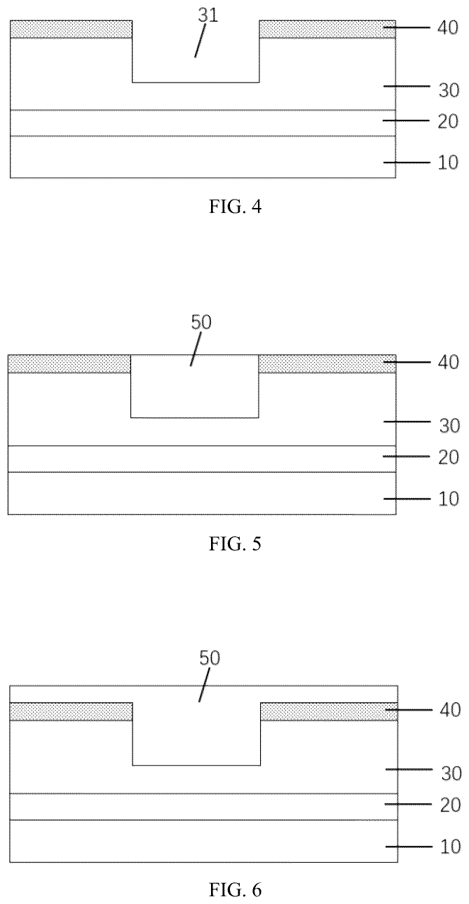

Specifically, as shown in FIG. 4, the first AlGaN layer 40 and the N− type gallium nitride epitaxial layer 30 are etched to form a trench 31 with a bottom located in the N− type gallium nitride epitaxial layer 30.

S3: performing a secondary epitaxy of a P-type gallium nitride epitaxial layer in the trench.

Specifically, as shown in FIG. 5, a second epitaxial of a P-type gallium nitride epitaxial layer 50 is performed in the trench 31. A method of performing the secondary epitaxy of the P-type gallium nitride epitaxial layer 50 is in-situ growth. Since the in-situ growth method does not introduce impurities on an interface, an interface quality between the N− type gallium nitride epitaxial layer 30 and the P-type gallium nitride epitaxial layer 50 may be improved, and a crystal quality of the P-type gallium nitride epitaxial layer 50 may be simultaneously improved.

In an embodiment, S3 further includes: performing a secondary epitaxy of an initial P-type gallium nitride epitaxial layer in the trench, where a thickness of the initial P-type gallium nitride epitaxial layer is greater than a depth of the trench; and chemically and mechanically polishing the initial P-type gallium nitride epitaxial layer to obtain the P-type gallium nitride epitaxial layer, where a thickness of the P-type gallium nitride epitaxial layer is equal to the depth of the trench.

Specifically, as shown in FIG. 6, the secondary epitaxy of the P-type gallium nitride epitaxial layer 50 is performed in the trench 31, a thickness of the P-type gallium nitride epitaxial layer 50 is greater than a depth of the trench 31. Chemical Mechanical Polishing (CMP) is performed on the P-type gallium nitride epitaxial layer 50 until a thickness of the P-type gallium nitride epitaxial layer 50 is equal to a depth of the trench 31, so as to form a semiconductor structure as shown in FIG. 5. Chemical mechanical polishing may remove an excess P-type gallium nitride epitaxial layer 50 on a surface of the first AlGaN layer 40 and obtain a surface that is both flat, free of scratches and impurities, it does not need to strictly control the thickness of the P-type gallium nitride epitaxial layer 50 during a growing process of the P-type gallium nitride epitaxial layer 50, and a surface quality of the semiconductor structure after chemical mechanical polishing is good.

S4: growing a second AlGaN layer on the P-type gallium nitride epitaxial layer and the first AlGaN layer.

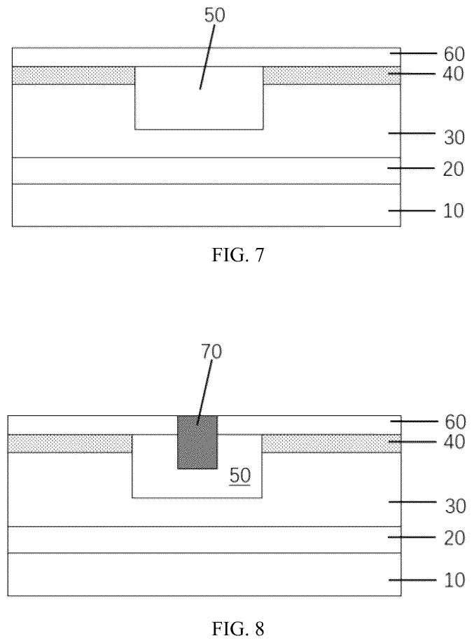

Specifically, as shown in FIG. 7, the second AlGaN layer 60 is grown on the P-type gallium nitride epitaxial layer 50 and the first AlGaN layer 40. A thickness of the second AlGaN layer 60 ranges from 10 nm to 100 nm, which may include an N-type doped ion.

S5: performing ion implantation on a surface of a side, away from the substrate, of the second AlGaN layer to form a source electrode extending into the P-type gallium nitride epitaxial layer.

Specifically, as shown in FIG. 8, ion implantation is performed on the surface of the side, away from the substrate 10, of the second AlGaN layer 60 to form the source electrode 70 extending into the P-type gallium nitride epitaxial layer 50. A material of the source electrode 70 includes an N-type heavily doped material, and an ion implanted in step S5 includes a silicon ion. A thickness of the P-type gallium nitride epitaxial layer 50 located below the source electrode 70 is greater than 50 nm, and a width of the P-type gallium nitride epitaxial layer 50 located on a side of a sidewall of the source electrode 70 is greater than 500 nm.

S6: disposing a dielectric layer on a side, away from the substrate, of the second AlGaN layer and the source electrode, disposing a drain electrode on a side, away from the dielectric layer, of the substrate, and disposing a gate electrode corresponding to the P-type gallium nitride epitaxial layer, on a side, away from the substrate, of the dielectric layer.

Specifically, the dielectric layer 71 is disposed on a side, away from the substrate 10, of the second AlGaN layer 60 and the source electrode 70, the drain electrode 72 is disposed on the side, away from the dielectric layer 71, of the substrate 10, and the gate electrode 73 corresponding to the P-type gallium nitride epitaxial layer 50 is disposed on the side, away from the substrate 10, of the dielectric layer 71, to form a semiconductor structure as shown in FIG. 1.

The present disclosure provides a semiconductor structure and a manufacturing method for the semiconductor structure. The semiconductor structure includes: a substrate, an N+ type gallium nitride epitaxial layer, an N− type gallium nitride epitaxial layer and a first AlGaN layer that are sequentially disposed; a P-type gallium nitride epitaxial layer extending from a surface of a side, away from the substrate, of the first AlGaN layer into the N− type gallium nitride epitaxial layer, and a second AlGaN layer located on a side, away from the substrate, of the first AlGaN layer and the P-type gallium nitride epitaxial layer.

In the present disclosure, through a PN junction depletion region formed by a P-type gallium nitride epitaxial layer and a N-type epitaxial layer coated with the P-type gallium nitride epitaxial layer, an enhancement mode device with a high threshold voltage may be realized, and a depletion region formed by the second AlGaN layer and the P-type gallium nitride epitaxial layer is controlled through a gate electrode, thereby controlling a switch of a device. At the same time, a gate electrode current does not need to pass through the P-type gallium nitride epitaxial layer completely, so that a large gate electrode current required by a traditional vertical device for controlling the P-type gallium nitride epitaxial layer is avoided, and a channel on an upper surface of the second AlGaN layer may be opened only by a small gate electrode current, so that the device has better reliability.

In the present disclosure, by providing the N− type gallium nitride epitaxial layer and the first AlGaN layer to form a heterojunction, a two-dimensional electron gas is generated, so that an electron mobility of a vertical structure device may be improved, an effect of expanding a vertical current range is achieved, and an on-resistance of the device may be effectively reduced. Meanwhile, a source electrode is connected to a transverse two-dimensional electron gas channel and a longitudinal conductive channel in the N-type epitaxial layer through a conductive channel of an interface between the dielectric layer and the second AlGaN layer, thereby realizing the opening of the device.

It should be understood that the terms “including” and its modification used in this disclosure are open-ended, that is, “including but not limited to”. The term “an embodiment” represents “at least one embodiment”; and the term “another embodiment” means “at least one another embodiment”. In this specification, a schematic description of foregoing terms does not have to be directed to a same embodiment or example. Furthermore, specific features, structures, materials, or characteristics described may be incorporated in an appropriate manner in any one or more embodiments or examples. In addition, without being contradictory, a person skilled in the art may combine and permutate different embodiments or examples described in this specification and features of different embodiments or examples.

The foregoing descriptions are merely exemplary embodiments of the present disclosure, but are not intended to limit the present disclosure. Any modification, an equivalent replacement, or the like made within a spirit and principles of the present disclosure shall be included in a protection scope of the present disclosure.

What is claimed is:

1. A semiconductor structure, comprising:
a substrate, an N+ type gallium nitride epitaxial layer, an N− type gallium nitride epitaxial layer and a first AlGaN layer that are sequentially disposed;
a P-type gallium nitride epitaxial layer extending from a surface of a side, away from the substrate, of the first AlGaN layer into the N− type gallium nitride epitaxial layer; and
a second AlGaN layer located on a side, away from the substrate, of the first AlGaN layer and the P-type gallium nitride epitaxial layer.

2. The semiconductor structure according to claim 1, wherein a thickness of the second AlGaN layer ranges from 10 nm to 100 nm.

3. The semiconductor structure according to claim 1, wherein the second AlGaN layer comprises an N-type doped ion.

4. The semiconductor structure according to claim 1, wherein the semiconductor structure further comprises:
a source electrode extending from a surface of a side, away from the substrate, of the second AlGaN layer into the P-type gallium nitride epitaxial layer;
a dielectric layer located on a side, away from the substrate, of the second AlGaN layer and the source electrode;
a drain electrode located on a side, away from the dielectric layer, of the substrate; and
a gate electrode located on a side, away from the substrate, of the dielectric layer and corresponding to the P-type gallium nitride epitaxial layer.

5. The semiconductor structure according to claim 4, wherein a material of the dielectric layer comprises at least one of silicon nitride, aluminum oxide, aluminum nitride and aluminum oxynitride.

6. The semiconductor structure according to claim 4, wherein a projection of the gate electrode on a plane where the substrate is located completely covers a projection of a surface of a side, close to the second AlGaN layer, of the P-type gallium nitride epitaxial layer on the plane where the substrate is located.

7. The semiconductor structure according to claim 4, wherein a projection area of the source electrode on a plane where the substrate is located is smaller than a projection area of the P-type gallium nitride epitaxial layer on the plane where the substrate is located.

8. The semiconductor structure according to claim 7, wherein a projection of the source electrode on the plane where the substrate is located is completely located in a projection of the P-type gallium nitride epitaxial layer on the plane where the substrate is located.

9. The semiconductor structure according to claim 4, wherein a material of the source electrode comprises an N-type heavily doped material.

10. The semiconductor structure according to claim 4, wherein a thickness of the P-type gallium nitride epitaxial layer located below the source electrode is greater than 50 nm, and a width of the P-type gallium nitride epitaxial layer located on a side of a sidewall of the source electrode is greater than 500 nm.

11. The semiconductor structure according to claim 1, wherein a two-dimensional electron gas is formed on an interface of the first AlGaN layer and the N− type gallium nitride epitaxial layer.

12. A manufacturing method for a semiconductor structure, comprising:
sequentially disposing a substrate, an N+ type gallium nitride epitaxial layer, an N− type gallium nitride epitaxial layer and a first AlGaN layer;
etching the first AlGaN layer and the N− type gallium nitride epitaxial layer to form a trench with a bottom located in the N− type gallium nitride epitaxial layer;
performing a secondary epitaxy of a P-type gallium nitride epitaxial layer in the trench; and
growing a second AlGaN layer on the P-type gallium nitride epitaxial layer and the first AlGaN layer.

13. The manufacturing method for the semiconductor structure according to claim 12, wherein a thickness of the P-type gallium nitride epitaxial layer located below the source electrode is greater than 50 nm, and a width of the P-type gallium nitride epitaxial layer located on a side of a sidewall of the source electrode is greater than 500 nm.

14. The manufacturing method for the semiconductor structure according to claim 12, wherein the manufacturing method for the semiconductor structure further comprises:
performing ion implantation on a surface of a side, away from the substrate, of the second AlGaN layer to form a source electrode extending into the P-type gallium nitride epitaxial layer; and
disposing a dielectric layer on a side, away from the substrate, of the second AlGaN layer and the source electrode, disposing a drain electrode on a side, away from the dielectric layer, of the substrate, and disposing a gate electrode corresponding to the P-type gallium nitride epitaxial layer, on a side, away from the substrate, of the dielectric layer.

15. The manufacturing method for the semiconductor structure according to claim 12, wherein the performing a secondary epitaxy of a P-type gallium nitride epitaxial layer in the trench comprises:
performing a secondary epitaxy of an initial P-type gallium nitride epitaxial layer in the trench, wherein a thickness of the initial P-type gallium nitride epitaxial layer is greater than a depth of the trench; and
chemically and mechanically polishing the initial P-type gallium nitride epitaxial layer to obtain the P-type gallium nitride epitaxial layer, wherein a thickness of the P-type gallium nitride epitaxial layer is equal to the depth of the trench.

16. The manufacturing method for the semiconductor structure according to claim 12, wherein a method of performing the secondary epitaxy of the P-type gallium nitride epitaxial layer in the trench is in-situ growth.

17. The manufacturing method for the semiconductor structure according to claim 14, wherein an ion implanted on the surface of the side, away from the substrate, of the second AlGaN layer comprises a silicon ion.

18. The manufacturing method for the semiconductor structure according to claim 12, wherein a thickness of the second AlGaN layer ranges from 10 nm to 100 nm.

19. The manufacturing method for the semiconductor structure according to claim 12, wherein the second AlGaN layer comprises an N-type doped ion.

20. The manufacturing method for the semiconductor structure according to claim 12, wherein an interface of the first AlGaN layer and the N− type gallium nitride epitaxial layer is configured to generate a two-dimensional electron gas.
